(19) United States
(12) Patent Application Publication
(10) Pub. No.: US 2004/0012935 A1
(43) Pub. Date: Jan. 22, 2004

(54) Printed wiring board

(75) Inventors: Hiroyoshi Tagi, Osaka (JP); Tetsuyoshi Ogura, Osaka (JP); Yutaka Taguchi, Osaka (JP); Toshiyuki Asahi, Osaka (JP); Tatsuo Ogawa, Osaka (JP)

Correspondence Address: McDERMOTT, WILL & EMERY, 600 13th Street, N.W., Washington, DC, 20005-3096, US

(73) Assignee: MATSUSHITA ELECTRIC INDUSTRIAL CO., LTD.

(21) Appl. No.: 10/613,050

(22) Filed: Jul. 7, 2003

(30) Foreign Application Priority Data
Jul. 16, 2002 (JP) P2002-207347

(51) Int. Cl. H05K 1/18

(52) U.S. Cl. 361/761

(57) ABSTRACT

A signal transmitting lead 105 is provided on an electrically insulating layer 103. Auxiliary leads 104A and 104B are provided while the auxiliary leads 104A and 104B are not in electrical contact with the signal transmitting lead 105. At least a part of the auxiliary leads 104A and 104B is covered with an electromagnetic shielding layer 106. Consequently, radiant noise from the inside or the outside of a printed wiring board can be suppressed without degrading characteristics of a signal which is transmitted through the signal transmitting lead 105.

### BACKGROUND OF THE INVENTION

1. Field of the Invention

The present invention relates to a printed wiring board used for electronic equipment such as information processing equipment and wireless communication equipment, which has a multilayer structure containing an electronic component such as a transistor and an integrated circuit. The invention particularly relates to the printed wiring board which requires control of electromagnetic noise caused by the built-in electronic component to suppress interference between electronic components and a manufacturing method thereof.

2. Description of the Related Art

Recently, there has been proposed a multilayer printed wiring board containing an electronic component in order to respond demand of further miniaturization. For example, a sheet which exerts flexibility by mixing an insulating material with fused silica, epoxy resin, and the like are used in the multilayer printed wiring board containing an electronic component. The multilayer printed wiring board is constructed in such a manner that sheets are arranged in multilayer and an electronic component such as the transistor and the integrated circuit is built in between the layers.

The electronic component including the transistor and the integrated circuit generates the electromagnetic noise. Therefore, when the electronic component is built in the printed wiring board, the electromagnetic noise generated in the board causes malfunction of the electronic equipment including the built-in electronic component in the vicinity of the printed wiring board and a problem that degradation in high-frequency characteristics of the electronic equipment occurs.

Particularly in the printed wiring board in which the miniaturization (including reduction in thickness) is promoted, signal transmitting wiring becomes denser in a wiring layer. As a result, mutual interference between signal transmitting leads is increased, and the degradation of the high-frequency characteristics and the malfunction of the electronic component are further easy to generate.

Further, in the electronic component built-in type of multilayer printed wiring board, there is the problem that unnecessary radiation generated by the built-in electronic component influences another built-in electronic component to cause malfunction.

In the related art, there is a structure of a printed wiring board as shown in FIG. 7 in order to solve the above-described problems. A printed wiring board 801 includes electrically insulating layers 803 and 803 which are laminated, a signal transmitting lead 805 and a ground lead 804 which are formed of copper on both surfaces and the inside of the electrically insulating layers 803 and 803, an inner via hole 808 which electrically connects the leads 805 and 804, and an electromagnetic shielding layer 806.

The electromagnetic shielding layer 806 is provided on the surface of the signal transmitting lead 805 which is located in the electrically insulating layer 803. The electromagnetic shielding layer 806 is made of a magnetic material having magnetic loss such as ferrite, and the electromagnetic shielding layer 806 is applied on the signal transmitting lead 805. The unnecessary radiation from the signal transmitting lead 805 is attenuated by the electromagnetic shielding layer 806.

However, in the above-described structure, since the desired signal is also simultaneously attenuated as the radiant noise is reduced, the degradation of the high-frequency characteristics consequently occurs.

### SUMMARY OF THE INVENTION

In view of the foregoing, it is a main object of the invention to provide a printed wiring board which effectively reduces the electromagnetic noise.

In order to achieve the above-described object, the printed wiring board of the invention includes an insulating board which includes a plurality of electrically insulating layers which are laminated, an electronic component which is built in the insulating board, a signal transmitting lead which is provided at an interlayer between the electrically insulating layers, an auxiliary lead which is provided on the insulating board so that the auxiliary lead is not electrically in contact with the signal transmitting lead, and an electromagnetic shielding layer which covers at least a part of the auxiliary lead. Consequently, the radiant noise from the inside and outside of the printed wiring board can be suppressed without degrading the high-frequency characteristics in the high-frequency signal.

In order to prevent the radiant noise for the electronic component, it is effective to provide the electromagnetic shielding layer in the vicinity of the electronic component. Though the electromagnetic shielding layer can be provided on the auxiliary lead and the signal transmitting lead, it is more difficult for the electromagnetic shielding layer to be provided on the signal transmitting lead due to the following reasons.

The signal transmitting lead cannot be arranged in a certain range of the electrically insulating layer, that is, a region where the electronic component is arranged as its center. This is because the signal transmitting lead is physically distorted to have an adverse effect on characteristics of the signal transmission as deformation of the electrically insulating layer is generated by the built-in electronic component, in the case that the signal transmitting lead is arranged in the region where the electronic component is built in or in the vicinity of the electronic component. For this reason, the signal transmitting lead cannot be provided on the surface of the electrically insulating layer in the region where the electronic component is arranged or in the vicinity of the electronic component. Accordingly, the electromagnetic shielding layer cannot be arranged in the vicinity of the region where the electronic component is built in, with the electromagnetic shielding layer being as close to the electronic component as possible. On the contrary, when the signal transmitting lead is separated from the electronic component to a position where the deformation of the electrically insulating layer caused by the built-in electronic component is eliminated, an area required for the provision of the signal transmitting lead is increased and it prevents high-density mounting, whereas the electromagnetic shielding layer can be provided without adversely affecting the signal transmitting lead.

On the other hand, the auxiliary lead provided in the invention does not transmit the signal, and does not affect the electrical characteristics of the printed wiring board. Accordingly, high accuracy is not required for a shape of the auxiliary lead, so that there is no problem even if the physical distortion is given to the auxiliary lead by providing the auxiliary lead on the surface of the electrically insulating layer in the region where the electronic component is arranged or in the vicinity of the electronic component. Therefore, the electromagnetic-shielding layer can be formed on the auxiliary lead provided on the surface of the electrically insulating layer in the region where the electronic component is arranged or in the vicinity of the electronic component. For this reason, in the structure of the invention in which the auxiliary lead is provided to arrange the electromagnetic shielding layer on the auxiliary lead, while the high density mounting is maintained, the suppression of the radiant noise to the electronic component can be achieved.

It is preferable that the electromagnetic shielding layer be made of the material having the magnetic loss. Accordingly, the radiant noise can be effectively suppressed.

It is preferable that the auxiliary lead be connected to ground potential. Accordingly, compared with the structure having only the auxiliary lead connected to the ground potential, the ground lead exhibiting the same electrical characteristics can be realized with smaller occupied area. Therefore, the further miniaturization of the printed wiring board can be achieved. By adopting the structure of the invention, the electronic component, which is hesitantly built in the printed wiring board for fear of the adverse effects (unnecessary radiation and the like) onto the periphery or for fear of the adverse effects from the periphery, can advantageously be built in the printed wiring board. Consequently, the kind of the electronic component which can be built in the printed wiring board is increased, so that the degree of freedom in the design of the printed wiring board is increased.

Even in the structure in which the auxiliary lead is not connected to the ground potential, the invention can obtain almost the same suppressing effect of the radiant noise as the case where the auxiliary lead is connected to the ground potential. In this case, since the auxiliary lead is not connected to the ground potential, there is no restriction in the design of the wiring pattern. Specifically, the wiring pattern of the auxiliary lead can be designed by utilizing an excess space in the various kinds of leads.

In the invention, it is preferable to provide the insulating film between the auxiliary lead and the electromagnetic shielding layer. Accordingly, the auxiliary lead and the electromagnetic shielding layer which are arranged through the insulating film function as a decoupling capacitor, so that the radiant noise from the inside and the outside of the printed wiring board can be further efficiently suppressed.

In the invention, it is preferable to provide the auxiliary lead between the signal transmitting leads. Accordingly, the mutual interference between the signal transmitting leads is efficiently suppressed.

In the invention, it is preferable to provide the auxiliary lead between the signal transmitting lead and the electronic component or between the two electronic components. Accordingly, the mutual interference between the signal transmitting lead and the electronic component or the mutual interference between the electronic components is efficiently suppressed.

In particular, when the auxiliary lead is provided opposing to one component surface in which strength of the unnecessary radiation from the electronic component is higher in both component surfaces of the electronic component, the mutual interference between the signal transmitting lead and the electronic component or the mutual interference between the electronic components can be efficiently suppressed. For example, a terminal forming surface of the electronic component can be cited as the component surface in which strength of the unnecessary radiation is higher, and sometimes the component surface located on the reverse side of the terminal forming surface can be also cited. Further, when the auxiliary lead is provided opposing to the terminal forming surface of the electronic component and the component surface located on the reverse side of the terminal forming surface respectively, the mutual interference can be surely suppressed.

In the invention, it is preferable to provide the auxiliary lead on a periphery of the electronic component so as to surround the electronic component. Accordingly, the radiant noise from the inside and the outside of the electronic component is efficiently suppressed.

It is preferable that the auxiliary lead be provided so that the upper surface of the electronic component is covered with the auxiliary lead. Accordingly, the radiant noise from the inside and the outside of the electronic component is efficiently suppressed.

It is preferable that the auxiliary lead comprise a first auxiliary lead which covers one of the surfaces of the electronic component and a second auxiliary lead which is provided on the periphery of the electronic component so as to surround the electronic component, and a conductor which electrically connects the first auxiliary lead to the second auxiliary lead is provided in the electrically insulating layer. Accordingly, the radiant noise from the inside and the outside of the electronic component is further efficiently suppressed. This reason is as follows.

A simple three-dimensional shielding is formed against the electronic component in such a manner that the first and second auxiliary leads (including the electromagnetic shielding layer) are electrically connected with the conductor. Consequently, the suppressing capability for the radiant noise is improved.

It is preferable that the plurality of conductors be provided along a width direction of a side face of the electronic component, further being arranged so that the opposite directions of the conductors which are adjacent to each other are unparallel to the width direction of the side face of the electronic component and the opposite directions are intersected in sequence. Accordingly, the number of conductors provided along the side face of the electronic component is increased. Further, the conductors are dispersedly arranged with regularity. As a result, the radiant noise from the inside and the outside of the electronic element is further efficiently suppressed.

In the invention, it is preferable to provide the electromagnetic shielding layer on the both surfaces of the auxiliary lead. Accordingly, the electromagnetic shielding effect is further increased.

In the invention, it is preferable to further provide the electromagnetic shielding layer which covers at least a part of the signal transmitting lead. Accordingly, the electromagnetic shielding effect is further increased.

It is preferable to provide the electromagnetic shielding layer on both surfaces of the signal transmitting lead. Accordingly, the electromagnetic shielding effect is further increased.

It is preferable that the insulating film be provided between the signal transmitting lead and the electromagnetic shielding layer which covers the signal transmitting lead. This enables the signal transmitting lead and the electromagnetic shielding layer to be electrically separated. Consequently, the high-frequency characteristics of the signal component which are transmitted through the signal transmitting lead are improved.

It is preferable that the signal transmitting lead be provided on both surfaces of the electrically insulating layer respectively, the conductor which connects the signal transmitting leads on both surfaces is provided so that the conductor penetrates through the electrically insulating layer, and the insulating film and the electromagnetic shielding layer are arranged apart from the conductor. Accordingly, the conductor is not in contact with the electromagnetic shielding layer, so that the physical degradation of the conductor or the degradation in the high-frequency characteristics of the high-frequency signal which is transmitted through the conductor can be prevented.

It is preferable that the electrically insulating layer be made of a composite material which is formed by mixing an epoxy resin and an inorganic filler.

In the invention, it is preferable that the auxiliary lead be connected to the ground potential and a length of the electromagnetic shielding layer is set to one fourth of a subject wavelength of suppression. Accordingly, the auxiliary lead having the electromagnetic shielding layer acts as a resonator in the subject wavelength of the suppression. This allows the unnecessary radiation of a certain frequency to be efficiently suppressed in the printed wiring board.

In the invention, it is preferable that the length of the electromagnetic shielding layer be set to half the subject wavelength of the suppression. Accordingly, the auxiliary lead having the electromagnetic shielding layer acts as a resonator in the subject wavelength of the suppression. This allows the unnecessary radiation of a certain frequency to be efficiently suppressed in the printed wiring board.

The manufacturing method of the printed wiring board of the invention includes the steps of preparing a transfer forming material and pattern-forming the auxiliary lead on the transfer forming material, pattern-forming the electromagnetic shielding layer formed on the auxiliary lead layer on the transfer forming material, and transferring the auxiliary lead from the transfer forming material to the electrically insulating layer by making the electromagnetic shielding layer abut on the electrically insulating layer.

It is preferable that the manufacturing method of the printed wiring board of the invention further include the step of forming the electromagnetic shielding layer on an outside surface of the auxiliary lead layer which is formed on the electrically insulating layer.

As described above, in the printed wiring board of the invention, the radiant noise from the inside and the outside of the printed wiring board can be suppressed without degrading the high-frequency of the high-frequency signal which is transmitted through the signal transmitting lead.

Since the electromagnetic shielding layer is provided on the auxiliary lead, the electrically mutual interference between the signal transmitting leads or between the electronic components can be suppressed, compared to the structure in which only the auxiliary lead is provided.

Since the ground having high shielding strength with the smaller occupied area can be formed, further miniaturization of the printed wiring board can be achieved. In particular, tolerance of the electrical characteristics of the electronic component which can be mounted on the board is widened.

Even if the auxiliary lead is not in contact with the ground potential, similarly to the structure in which the ground electromagnetic shielding layer is formed, the suppressing effect of the radiant noise is obtained. In this case, since the auxiliary lead is not in contact with the ground potential, the auxiliary lead and the like can be formed by utilizing the excess space generated in the wiring pattern without the restriction on the design.

The radiant noise from the inside and the outside of the printed wiring board can be easily suppressed without changing the size of the printed wiring board.

Since the simple three-dimensional shielding against the built-in electronic component can be formed, the suppressing capability of the radiant noise is further improved.

The conductor is dispersedly arranged with the regularity, so that the suppressing capability of the radiant noise is further improved.

In the invention, since the electromagnetic shielding layer can function as the resonator in the subject frequency of the suppression, the unnecessary radiation of the certain frequency can be efficiently suppressed in the printed wiring board.

In the invention, the electromagnetic shielding layer is formed on the both surfaces of the auxiliary lead, so that the suppressing capability of the radiant noise can be further improved.

In the invention, the conductor can be prevented from being in contact with the electromagnetic shielding layer, so that the degradation of the conductor and the degradation of the high-frequency characteristics of the high-frequency signal can be prevented.

### BRIEF DESCRIPTION OF THE DRAWINGS

Other and further objects of the invention will become obvious upon an understanding of the illustrative embodiments about to be described or will be indicated in the appended claims, and various advantages not referred to herein will occur to those skilled in the art upon employment of the invention in practice.

FIG. 1A is a sectional view of a printed wiring board showing a first embodiment of the invention;

FIG. 1B is a sectional view of the printed wiring board showing a modification of the first embodiment of the invention;

FIG. 1C is a sectional view of the printed wiring board showing another modification of the first embodiment of the invention;

FIG. 2 is a sectional view of an electronic component built-in type of printed wiring board showing a second embodiment of the invention;

FIG. 3 is a sectional view of a wiring layer of the printed wiring board showing a third embodiment of the invention;

FIGS. 4A to 4D are sectional views of the electronic component built-in type of printed wiring board showing a fourth embodiment of the invention;

FIG. 4E is an enlarged view of a main part of the fourth embodiment;

FIG. 5A is a sectional view of the printed wiring board showing a first structure of a fifth embodiment of the invention;

FIG. 5B is a sectional view of the printed wiring board showing a second structure of the fifth embodiment of the invention;

FIGS. 6A to 6D are explanatory views of a manufacturing method of the printed wiring board of the invention; and

FIG. 7 is a sectional view of the printed wiring board the related art.

### DETAILED DESCRIPTION OF THE INVENTION

Embodiments of the invention are described below referring to the accompanying drawings.

(First Embodiment)

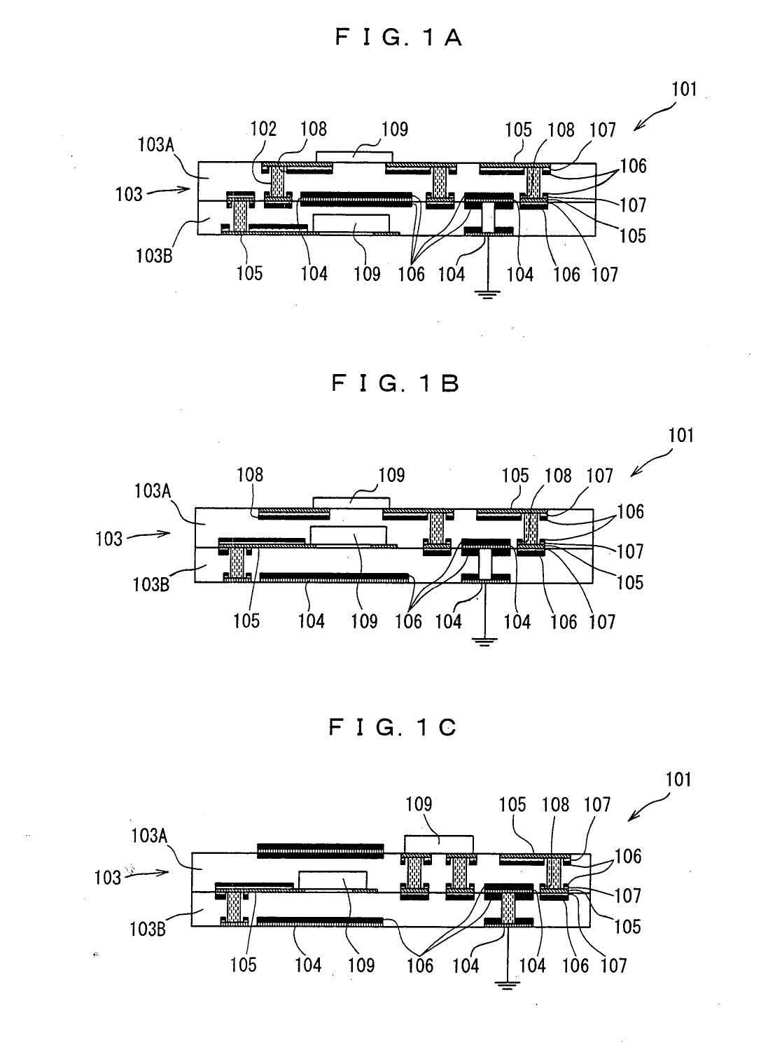

FIG. 1A is the sectional view of the electronic component built-in type of printed wiring board 101 showing a first embodiment of the invention. The printed wiring board 101 has an insulating board 103. The insulating board 103 has double electrically insulating layers 103A and 103B which are integrally formed. The electrically insulating layers 103A and 103B include a composite material in which an epoxy resin and an inorganic filler such as fused silica or alumina are mixed together. The electrically insulating layers 103A and 103B have an inner via hole 102. The inner via hole 102 includes a thermosetting resin containing conductive particles and the like. The inner via hole 102 is made through a thickness direction of the electrically insulating layers 103A and 103B. The electrically insulating layers 103A and 103B have a signal transmitting lead 105 and an auxiliary lead 104. The signal transmitting lead 105 and the auxiliary lead 104 are provided on both surfaces of the electrically insulating layers 103A and 103B. The transmission and the reception of the signal are performed between the printed wiring board 101 and the outside through the signal transmitting lead 105. The auxiliary lead 104 is arranged so as not to be in contact with the signal transmitting lead 105, i.e. so as to be electrically insulated from the signal transmitting lead 105. The auxiliary 104 is connected to ground potential. The auxiliary lead 104 functions as a ground lead. The signal transmitting lead 105 is arranged on both surfaces of the insulating board 103 and between the electrically insulating layers 103A and 103B respectively. The auxiliary lead 104 is arranged between the electrically insulating layers 103A and 103B. The inner via hole 102 electrically connects the two signal transmitting leads 105 and 105 or the two auxiliary leads 104 and 104.

An electromagnetic shielding layer 106 is provided on the signal transmitting lead 105 and the auxiliary lead 104. The electromagnetic shielding layer 106 is made of a magnetic material having magnetic loss. Specifically the electromagnetic shielding layer 106 is made of the material having the magnetic loss such as ferrite.

The electromagnetic shielding layer 106 is provided on the leads 105 and 104 and between the electrically insulating layers 103A and 103B. Surfaces of the leads 105 and 104 on the side of the electrically insulating layer are thoroughly covered with the electromagnetic shielding layer 106 between the leads. With reference to the electromagnetic shielding layer 106 provided on the signal transmitting lead 105 and the auxiliary lead 104 at an interlayer between the electrically insulating layers 103A and 103B, the electromagnetic shielding layer 106 is provided on both surfaces of the leads 105 and 104. Both surfaces of the leads 105 and 104 provided between the electrically insulating layers 103A and 103B are also thoroughly covered with the electromagnetic shielding layer 106.

An insulating film 107 is provided between the signal transmitting lead 105 and the electromagnetic shielding layer 106. The insulating film 107 is not provided between the electromagnetic shielding layer 106 and the auxiliary lead 104. The reason is as follows. When the electromagnetic shielding layer 106 is provided on the signal transmitting lead 105, attenuation occurs in the transmitted signal. In the embodiment, the attenuation is suppressed by providing the insulating film 107 between the signal transmitting leads 105 and the electromagnetic shielding layer 106. On the other hand, in the auxiliary lead, it is not necessary to provide the insulating film 107 because the signal is not transmitted.

An inner via inserting hole 108 is formed in the electromagnetic shielding layer 106 and the insulating film 107, which are provided on the signal transmitting lead 105. The inner via inserting hole 108 is provided in a region where the inner via hole 102 is formed. The inner via inserting hole 108 has a slightly larger diameter than that of the inner via hole 102. The inner via hole 102 is arranged concentrically with the inner via inserting hole 108. Accordingly, the inner via hole 102 is electrically connected to the signal transmitting lead 105 while the inner via hole 102 is only in contact with the signal transmitting lead 105 without being in contact with the electromagnetic shielding layer 106 and the insulating film 107. The inner via hole 102 allows the two signal transmitting leads 105 to be electrically connected to each other with high-frequency characteristics maintained.

The inner via inserting hole 108 is not formed on the electromagnetic shielding layer 106 provided on the auxiliary lead 104. This is because the signal is not transmitted through the auxiliary lead 104. The interlayer connection of the auxiliary lead 104 may be electrical only and high electrical characteristics are not particularly required.

An electronic component 109 is mounted on the printed wiring board 101. The electronic component 109 is electrically connected to the signal transmitting leads 105 of the lowermost layer and the uppermost layer. The electronic component 109 electrically connected to the signal transmitting lead 105 of the lowermost layer is built in the electrically insulating layer 103B on the lower side. The electronic component 109 electrically mounted on the signal transmitting lead 105 of the uppermost layer is installed on the upper surface of the electrically insulating layer 103A (printed wiring board 101) on the upper side. The electronic components 109 are arranged on opposite sides along the thickness direction of the printed wiring board 101. The auxiliary lead 104 is arranged between the electronic components 109. The auxiliary lead 104 is arranged so as to obstruct the two electronic components 109.

In the embodiment, the electromagnetic shielding layer 106 is provided on the auxiliary lead 104. Further, the electromagnetic shielding layer 106 is provided on both surfaces of the auxiliary lead 104 arranged in the interlayer of the electrically insulating layers 103. This allows the radiant noise to be efficiently suppressed. In the embodiment, the electromagnetic shielding layer 106 is also provided on the signal transmitting lead 105. This is the constitution adopted for putting the highest priority on the suppression of the radiant noise. However, in the case where compatibility of the suppression of the radiant noise with the high-density mounting is required, the electromagnetic shielding layer 106 is not provided on the signal transmitting lead 105, and the electromagnetic shielding layer 106 may be provided only on the auxiliary lead 104.

In the embodiment, the electromagnetic shielding layer 106 is arranged between the electronic components 109 which are arranged on opposite side along the thickness direction of the printed wiring board 101. The electromagnetic shielding layer 106 is formed on both surfaces of the auxiliary lead (ground) 104 respectively. Accordingly, electrically mutual interference between the electronic components 109 is further efficiently suppressed, compared with the constitution having only the auxiliary lead (ground) 104.

In the constitution having the electromagnetic shielding layer 106, the ground having the same shielding strength can be formed by the smaller occupied area, compared with the constitution not having the electromagnetic shielding layer 106. Accordingly, further miniaturization of the printed wiring board 101 can be achieved, and tolerance of characteristics in the electronic component 109 which is regarded as being mountable on the printed wiring board 101 is widened.

Since the inner via hole 102 is formed so as not to abut on the electromagnetic shielding layer 106, a conductive paste constituting the inner via hole 102 is not in contact with the electromagnetic shielding layer 106. Accordingly, physical degradation of the conductive paste and the characteristic degradation of the high-frequency signal transmitted through the inner via hole 102 are prevented.

With reference to the signal transmitting lead 105, the insulating film 107 is provided between the signal transmitting lead 105 and the electromagnetic shielding layer 106, so that the characteristics of the high-frequency signal transmitted through the inner via hole 102 are not degraded. Accordingly, the radiant noise from the inside of the printed wiring board 101 toward the outside or the radiant noise penetrated from the outside to the inside can be further efficiently suppressed. This reason is as follows. The electromagnetic shielding layer 106 is formed on the signal transmitting lead 105 through the insulating film 107, which allows the noise from the outside (unnecessary electromagnetic field) to be surely attenuated before the noise affects the electromagnetic field of the signal transmitted through the signal transmitting lead 105. Similarly, the unnecessary electromagnetic field from the signal transmitted through the signal transmitting lead 105 is surely suppressed by the electromagnetic shielding layer 106, so that it is further difficult for the noise generated within the board to leak outside.

Though the auxiliary lead 104 and the electromagnetic shielding layer 106 are provided so as to cover the upper side of the electronic component 109 in FIG. 1A, the auxiliary lead 104 and the electromagnetic shielding layer 106 may be provided so as to cover the lower side (terminal forming surface) of the electronic component 109 as shown in FIG. 1B. Further, as shown in FIG. 1C, the auxiliary lead 104 and the electromagnetic shielding layer 106 may be provided so as to cover both the upper side and the lower side of the electronic component 109.

(Second Embodiment)

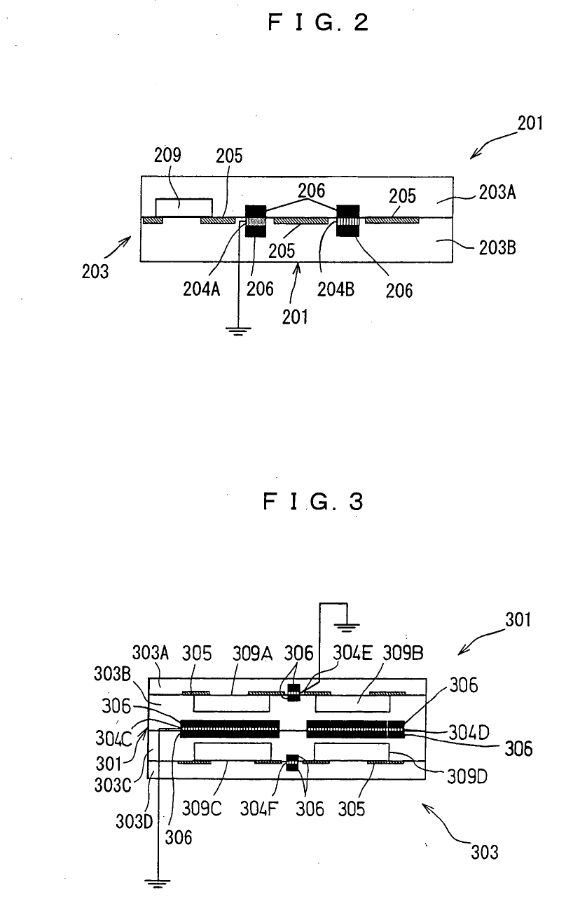

FIG. 2 is the sectional view of the electronic component built-in type of printed wiring board showing a second embodiment of the invention. A printed wiring board 201 shown in FIG. 2 has an insulating board 203. The insulating board 203 has double electrically insulating layers 203A and 203B which are integrally laminated. The electrically insulating layers 203A and 203B include the composite material in which the epoxy resin and the inorganic filler such as the fused silica or the alumina are mixed together. A signal transmitting lead 205, auxiliary leads 204A and 204B, and an electronic component 209 are arranged in the interlayer of the electrically insulating layers 203A and 203B. The auxiliary leads 204A and 204B are arranged between the signal transmitting leads 205. The auxiliary lead 204A is connected to the ground potential. On the other hand, the auxiliary lead 204B is not connected to the ground potential (not shown), and it becomes a so-called non-connection. The electromagnetic shielding layer 206 is formed over both surfaces of the auxiliary leads 204A and 204B. The electromagnetic shielding layer 206 is made of the magnetic material having the magnetic loss. The electronic component 209 is electrically connected to the signal transmitting lead 205. The electronic component 209 is built in the electrically insulating layers 203A on the upper side.

In the embodiment, the auxiliary leads 204A and 204B are arranged between the adjacent signal transmitting leads 205 and 205, and the electromagnetic shielding layer 206 is provided on both surfaces of the auxiliary leads 204A and 204B. Accordingly, the electrically mutual interference between the signal transmitting leads 205 and 205 is efficiently suppressed, compared to the structure in which only the auxiliary leads 204A and 204B are provided. Further, the ground having the same shielding strength can be formed by the smaller area. Accordingly, further miniaturization of the printed wiring board can be achieved. The tolerance of the characteristics of the mountable electronic component 209 is widened.

The auxiliary lead 204A is connected to the ground potential. The auxiliary lead 204A further efficiently suppresses the electrically mutual interference between the signal transmitting leads 205 and 205.

(Third Embodiment)

FIG. 3 is the sectional view of an electronic component built-in type of printed wiring board 301 showing a third embodiment of the invention. The printed wiring board 301 has an insulating board 303. The insulating board 303 has four electrically insulating layers 303A to 303D which are integrally laminated. The electrically insulating layers 303A to 303D include the composite material in which the epoxy resin and the inorganic filler such as the fused silica or the alumina are mixed together. A signal transmitting lead 305, auxiliary leads 304A to 304F, and electronic components 309A to 309D are arranged in the interlayer of the electrically insulating layers 303A to 303D.

The electronic components 309A to 309D are mounted on a signal transmitting lead 305 to be electrically connected. The electronic components 309A and 309B are arranged on the same surface (between the electrically insulating layers 303A and 303B) in the insulating board 303 and embedded in the electrically insulating layer 303B. The electronic components 309C and 309D are arranged on the same surface (between the electrically insulating layers 303C and 303D) in the insulating board 303 and embedded in the electrically insulating layer 303C. Thus the group of electronic components 309A and 309B and the group of electronic components 309C and 309D are arranged on different surfaces. The electronic components 309A and 309C are arranged on opposite sides along the thickness direction of the printed wiring board 301B. The electronic components 309B and 309D are arranged on opposite sides along the thickness direction of the printed wiring board 301B.

The auxiliary leads 304C and 304D are arranged on the same surface (between the electrically insulating layers 303B and 303C) in the insulating board 303. The auxiliary lead 304C is arranged at a position which obstructs the electronic components 309A and 309C. The auxiliary lead 304D is arranged at a position which obstructs the electronic components 309B and 309D.

The auxiliary lead 304E is arranged on the same surface (between the electrically insulating layers 303A and 303B) as the electronic components 309A and 309B. The auxiliary lead 304E is arranged at a position where the auxiliary lead 304E obstructs the electronic components 309A and 309B. The auxiliary lead 304F is arranged on the same surface (between the electrically insulating layers 303A and 303B) as the electronic components 309A and 309B. The auxiliary lead 304F is arranged at a position where the auxiliary lead 304F obstructs the electronic components 309C and 309D.

An electromagnetic shielding layer 306 is provided on both surfaces of the auxiliary leads 304C to 304F. The electromagnetic shielding layer 306 is made of the magnetic material having magnetic loss. The electromagnetic shielding layer 306 is formed over the entire surfaces of the auxiliary leads 304C to 304F. The auxiliary leads 304C and 304E are connected to ground potential (not shown). On the other hand, the auxiliary leads 304D and 304F are not connected to the ground potential, and become so-called non-connections.

In the embodiment, the auxiliary leads 304C to 304F are arranged between the adjacent signal transmitting leads 305 and 305 or the electronic components 309A to 309D, and the electromagnetic shielding layer 306 is provided on both surfaces of the auxiliary leads 304C to 304F. Accordingly, in this structure, the electrically mutual interference between the signal transmitting leads 305 and 305 or among the electronic components 309A to 309D is efficiently suppressed compared to the structure in which only the auxiliary leads 304C to 304F are provided. Further, the ground having the same shielding strength can be formed by the smaller area. Accordingly, further miniaturization of the printed wiring board can be achieved. The tolerance of the characteristics of the mountable electronic component is widened.

The auxiliary leads 304C and 304E are connected to the ground potential. The auxiliary leads 304C and 304E further efficiently suppress the electrically mutual interference between the signal transmitting leads 305 and 305 or among the electronic components 309A to 309D.

(Fourth Embodiment)

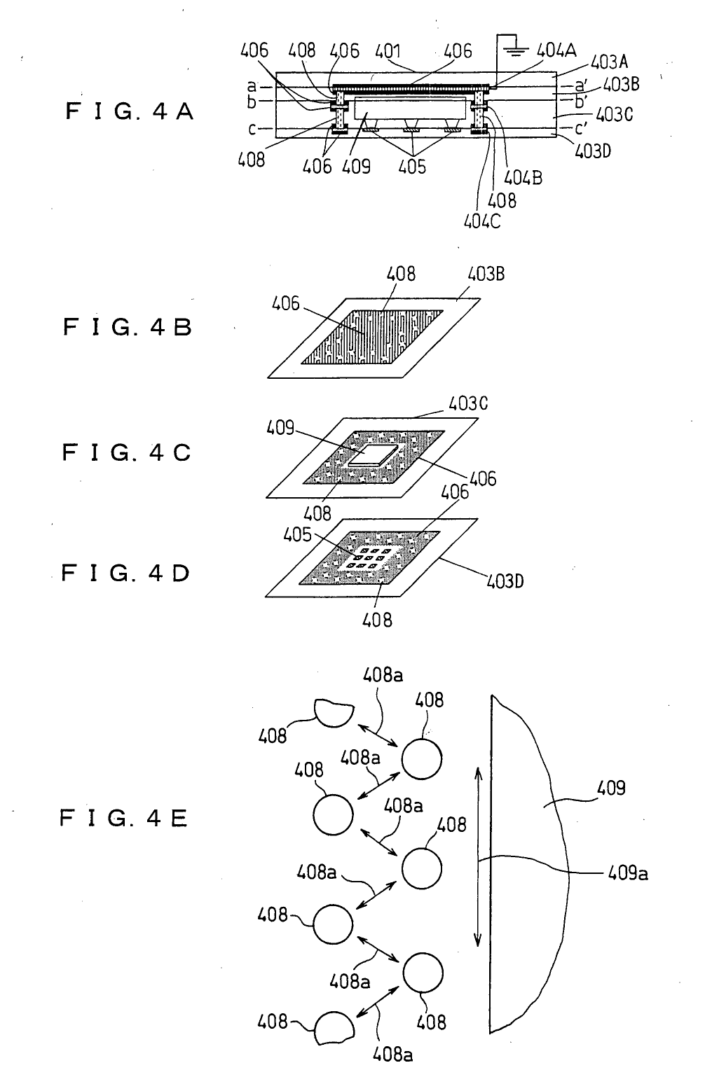

FIG. 4 is the sectional view of the electronic component built-in type of printed wiring board showing a fourth embodiment of the invention. FIG. 4A is the sectional view of the electronic component built-in type of printed wiring board, FIG. 4B is the sectional view taken on line a-a′ of FIG. 4A, FIG. 4C is the sectional view taken on line b-b′ of FIG. 4A, FIG. 4D is the sectional view taken on line c-c′ of FIG. 4A, and FIG. 4E is the enlarged view of the main part showing the arrangement of the inner via holes.

An electronic component built-in type of printed wiring board 401 has an insulating board 403. The insulating board 403 has four electrically insulating layers 403A to 403D which are integrally laminated. The electronic component 409 is built in on the interlayer between the electrically insulating layers 403 and 403. A signal transmitting lead 405, a first auxiliary lead 404A, and second auxiliary leads 404B and 404C are arranged in the interlayer between the electrically insulating layers 403. The signal transmitting lead 405 is connected to the electronic component 409. The electronic component 409 is mounted on the signal transmitting lead 405. The electronic component 409 is built in the electrically insulating layer 403.

The first auxiliary lead 404A is plane-shaped, and arranged at a position where the upper surface of the electronic component 409 is covered with the first auxiliary lead 404A. At this point, the upper surface of the electronic component 409 indicates a component surface which is located on a reverse side of the terminal forming surface. The second auxiliary leads 404B and 404C are frame-shaped, and arranged at the position which surrounds a periphery of the electronic component 409. The first auxiliary lead 404A and the second auxiliary leads 404B and 404C are respectively arranged on the different surfaces in the insulating board 403. Specifically the first auxiliary lead 404A is arranged in the interlayer between the electrically insulating layers 403A and 403B. The first auxiliary lead 404A is connected to the ground potential. The second auxiliary lead 404B is arranged in the interlayer between the electrically insulating layers 403B and 403C. The second auxiliary lead 404C is arranged in the inter layer between the electrically insulating layers 403C and 403D.

The inner via holes 408 are built in the printed wiring board 401. The inner via holes 408 are provided between the first auxiliary lead 404A and the second auxiliary lead 404B and between the second auxiliary lead 404B and the second auxiliary lead 404C respectively. The first auxiliary lead 404A is electrically connected to the second auxiliary lead 404B with the inner via hole 408. The second auxiliary lead 404B is electrically connected to the second auxiliary lead 404C with the inner via hole 408. The second auxiliary leads 404B and 404C are connected to the ground potential through the first auxiliary lead 404A.

An electromagnetic shielding layer 406 is provided on both surfaces of the first auxiliary lead 404A and the second auxiliary leads 404B and 404C. The electromagnetic shielding layer 406 is formed over both surfaces of the first auxiliary lead 404A and the second auxiliary leads 404B and 404C. The electromagnetic shielding layer 406 is made of the magnetic material having magnetic loss. The electromagnetic shielding layer 406 is connected to the inner via hole 408. Accordingly, the electromagnetic shielding layers 406 of each layer are electrically connected to each other. The electromagnetic shielding layer 406 is also electrically connected to the first auxiliary lead 404A and the second auxiliary leads 404B and 404C.

As shown in FIG. 4E, the plurality of inner via holes 408 which connect the first auxiliary lead 404A to the second auxiliary lead 404B are provided along a width direction 409a of a side face of the electronic component 409. Similarly the plurality of inner via holes 408 which connect the second auxiliary lead 404B to the second auxiliary lead 404C are provided along a width direction 409a of the side face of the electronic component 409. Opposite directions 408a of the inner via holes 408 and 408, which are adjacent to each other, are set to be unparallel to the width direction 409a of the side face of the electronic component 409. The opposite directions 408a are intersected in sequence.

In the printed wiring board 401, the signal transmitting lead 405, the inner via hole 408, and the like which can secure the reliability cannot be formed in a region close to the electronic component 409. That is to say, because the electrically insulating layer 403 in the vicinity of the electronic component 409 is physically distorted by containing the electronic component 409, the signal transmitting lead 405 or the inner via hole 408 is also physically distorted when the signal transmitting lead 405 or the inner via hole 408 is provided in the electrically insulating layers 403.

However, in the constitution of the embodiment, the first auxiliary lead 404A and the second auxiliary leads 404B and 404C, in which the reliability is not required so much, are arranged in the vicinity of the electronic component 409. Further, the inner via hole 408 for connecting the interlayers of the first auxiliary lead 404A and the second auxiliary lead 404B and 404C is arranged in the vicinity of the electronic component 409.

Thus, in the embodiment, the first auxiliary lead 404A and the second auxiliary lead 404B and 404C or the inner via hole 408 for connecting the interlayers of the first auxiliary lead 404A and the second auxiliary lead 404B and 404C are provided in the vicinity of the built-in electronic component 409, where the lead and its structure for connecting the interlayers have not been arranged in the related art. Accordingly, the radiant noise from the inside or the outside of the printed wiring board 401 can be suppressed without increasing the size of the printed wiring board 401.

The electromagnetic shielding layer 406 of each layer is electrically connected to the first auxiliary lead 404A and the second auxiliary lead 404B and 404C through the inner via holes 408 which are dispersedly arranged with regularity, so that a three-dimensional shielding is simply formed against the electronic component 409. Therefore, the suppressing capability of the radiant noise is improved compared to the structure in which the electromagnetic shielding layer 406 is independently formed. The suppressing capability of the radiant noise is further improved by dispersedly arranging the inner via holes 408 with regularity. This is because the inner via holes 408 can be more precisely arranged along the width direction 408a of the side face of the electronic component 409 by dispersedly arranging the inner via holes 408 with regularity.

(Fifth Embodiment)

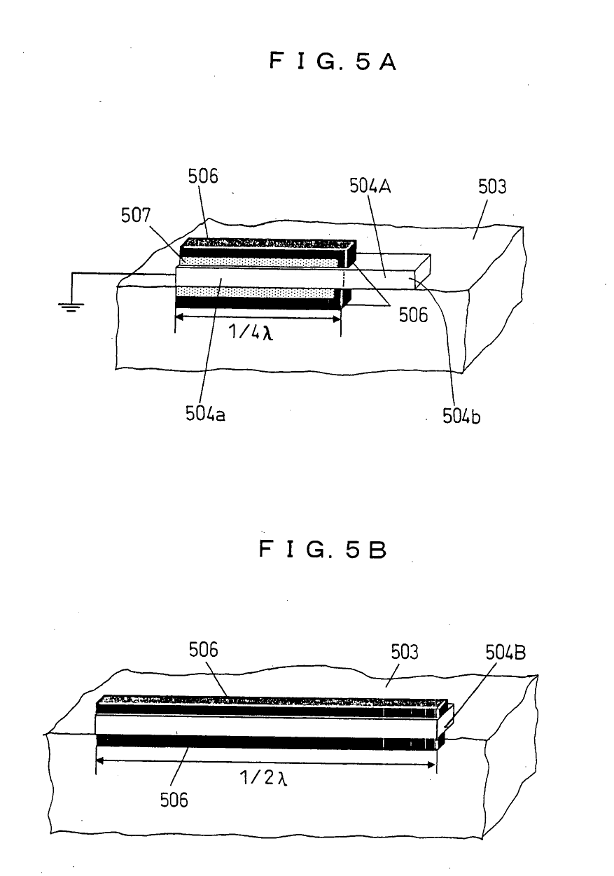

FIG. 5A is the sectional view of the printed wiring board showing a first structure of the fifth embodiment of the invention. In the structure, an electromagnetic shielding layer 506 is provided on both surfaces of an auxiliary lead 504A connected to the ground potential. The electromagnetic shielding layer 506 is made of the magnetic material having magnetic loss. An insulating film 507 is provided between the electromagnetic shielding layer 506 and the auxiliary lead 504A.

The electromagnetic shielding layer 506 is provided in the following region on the auxiliary lead 504A. The electromagnetic shielding layer 506 is formed on a region 504a in a longitudinal direction of the auxiliary lead 504A, which has one-fourth length of a wavelength corresponding to the subject frequency of the suppression. The electromagnetic shielding layer 506 is not formed in other region 504b of the auxiliary lead 504A.

FIG. 5B is the sectional view showing a second structure of the embodiment. In the structure, an auxiliary lead 504B (non-connection) which is not connected to the ground potential is formed in half length of the wavelength corresponding to the subject frequency of the suppression. The electromagnetic shielding layer 506 is provided on both surfaces of the auxiliary lead 504B. The insulating film is not provided between the electromagnetic shielding layer 506 and the auxiliary lead 504B.

A numeral reference 503 indicates the electrically insulating layer in FIGS. 5A and 5B.

In the first structure of the embodiment shown in FIG. 5A, the electromagnetic shielding layer 506 is selectively formed on the region 504a in the longitudinal direction of the auxiliary lead 504A, which has one-fourth length of the wavelength corresponding to the subject frequency of the suppression. The electromagnetic shielding layer 506 functions as a resonator in the subject frequency of the suppression. Consequently, the unnecessary radiation in a certain frequency is suppressed within the printed wiring board.

In the second structure of the embodiment shown in FIG. 5B, the auxiliary lead 504B is formed over the half length of the wavelength corresponding to the subject frequency of the suppression, and the electromagnetic shielding layer 506 is formed over both surfaces of the auxiliary lead 504B. The auxiliary lead 504B functions as the resonator in the subject frequency of the suppression. Consequently, the unnecessary radiation in a certain frequency is suppressed within the printed wiring board.

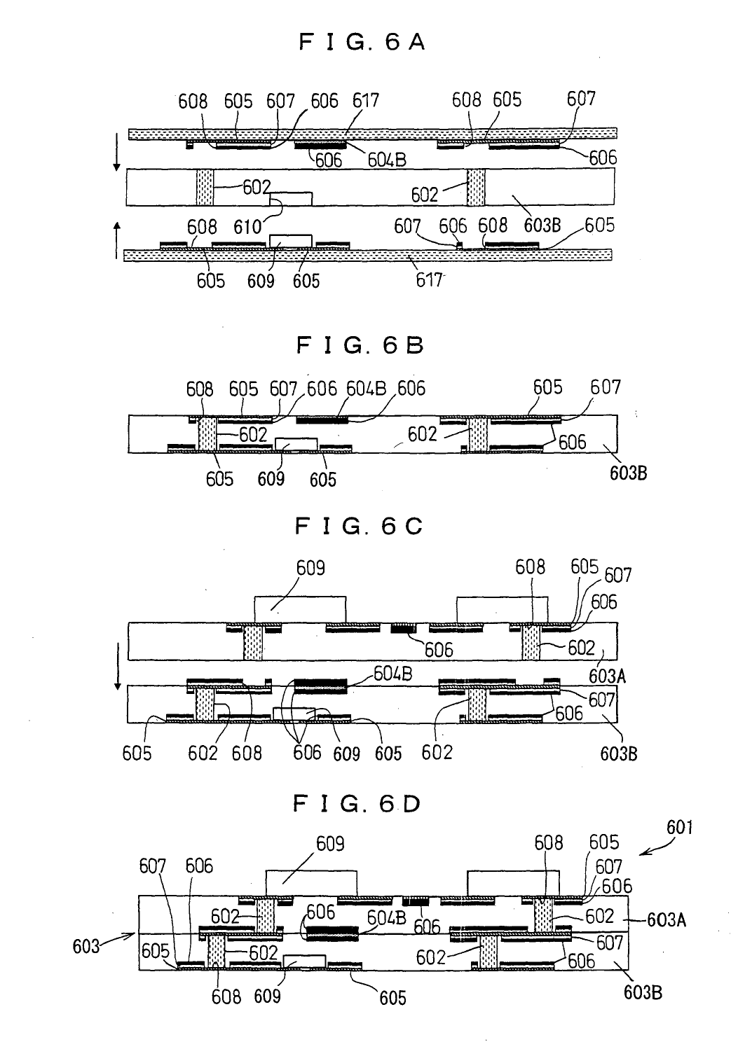

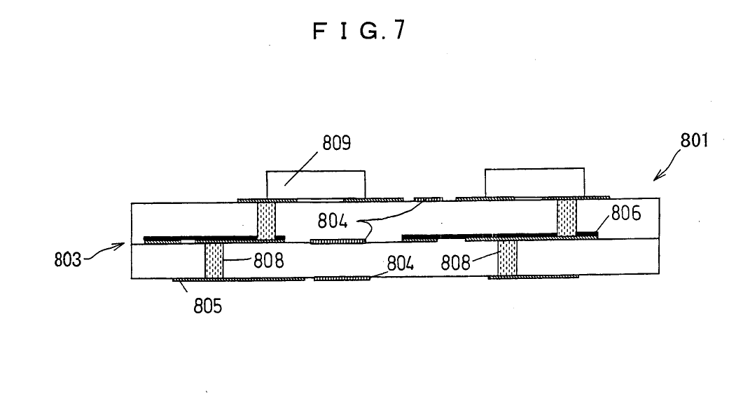

The manufacturing method of the printed wiring board of the invention is described below referring to FIG. 6. Though the manufacturing method described below is similar to the printed wiring board 101 in the first embodiment, which has an auxiliary lead 604A connected to the ground potential and an auxiliary lead 604B not connected to the ground potential.

As shown in FIG. 6A, a transfer forming material 617 is prepared. The auxiliary lead 604A connected to the ground potential, a signal transmitting lead 605, and the auxiliary lead 604B not connected to the ground potential are formed on the transfer forming material 617. The leads 604A, 604B, and 605 are formed on the transfer forming material 617 by a printing method or a subtractive method.

An insulating film 607 is selectively formed on the signal transmitting lead 605. The insulating film 607 is formed on the signal transmitting lead 605 by, for example, the printing method or the subtractive method.

An electromagnetic shielding layer 606 made of the magnetic material having magnetic loss is formed on the insulating film 607 (signal transmitting lead 605) and the auxiliary leads 604A and 604B. The electromagnetic shielding layer 606 is formed on the insulating film 607 and the auxiliary leads 604A and 604B by, for example, the printing method or the subtractive method.

An inner via inserting hole 608 which reaches the signal transmitting lead 605 is formed in the electromagnetic shielding layer 606 and the insulating film 607 on the signal transmitting lead 605. The inner via inserting hole 608 is formed at a position which is opposite to an inner via hole 602 subsequently formed. The inner via inserting hole 608 is formed by, e.g. the subtract method. The inner via inserting hole 608 is formed in the diameter slightly larger than that of the inner via hole 602. Further, an electronic component 609 is mounted on a predetermined position of the signal transmitting lead 605 to be electrically connected.

On the other hand, an electrically insulating layer 603B is prepared. An electronic component storing hole 610 is formed in the electrically insulating layer 603B. The electronic component storing hole 610 has dimensions in which the electronic component 609 is inserted. Further, a through hole is formed in the electrically insulating layer 603B. The through hole is filled with a conductive paste. The conductive paste filled in the through hole constitutes the inner via hole 602.

The transfer forming material 617 is bonded to the electrically insulating layer 603B. The transfer forming material 617 is arranged so that the formed surfaces of the auxiliary leads 604A and 604B are opposite to the electrically insulating layer 603. At this point, the transfer forming material 617 is arranged so that the electronic component 609 intrudes into the electronic component storing hole 610. Accordingly, the auxiliary leads 604A and 604B and the signal transmitting lead 605 are transferred to the electrically insulating layer 603B with the insulating film 607 and the signal transmitting lead 605. The transfer forming material 617 is removed from the electrically insulating layer 603B after the transfer. The signal transmitting lead 605 after the transfer is electrically connected while the signal transmitting lead 605 is in direct contact with the inner via hole 602 as shown in FIG. 6B. At this point, the insulating film 607 and the electromagnetic shielding layer 606 do not abut on the inner via hole 602 by the inner via inserting hole 608.

The signal transmitting lead 605 is formed on the electrically insulating layer 603B, and the insulating film 607 and the electromagnetic shielding layer 606 are formed on the auxiliary leads 604A and 604B. The insulating film 607 and the electromagnetic shielding layer 606 are formed by, for example, the printing method or the subtractive method.

The inner via inserting hole 608 which reaches the signal transmitting lead 605 is formed in the electromagnetic shielding layer 606 and the signal transmitting lead 605 on the signal transmitting lead 605. The inner via inserting hole 608 is formed at the position which is opposite to the inner via hole 602 subsequently formed. The inner via inserting hole 608 is formed by, for example, the subtract method. The inner via inserting hole 608 is formed in the diameter slightly larger than that of the inner via hole 602.

One more electrically insulating layer 603A is prepared. The inner via hole 602, the signal transmitting lead 605, the auxiliary leads 604A and 604B, the electromagnetic shielding layer 606, the insulating film 607, and the inner via inserting hole 608 are formed in such a manner that the same processes as those in FIGS. 6A and 6B are performed to the electrically insulating layer 603A. However, the signal transmitting lead 605, the auxiliary leads 604A and 604B, the electromagnetic shielding layer 606, and the insulating film 607 are formed on only one surface of the electrically insulating layer 603. Then, one more electronic component 609 is mounted on the signal transmitting lead 605 of the electrically insulating layer 603.

Both electrically insulating layers 603A and 603B are integrally laminated to become the insulating board 603. At this point, the electrically insulating layer 603A of which various leads are formed on one surface is laminated so that the surface on which no lead is formed is opposite to the electrically insulating layer 603B which is the counterpart of the electrically insulating layer 603A. One more electrically insulating layer 603B is formed so that the formed surface of inner via inserting hole is opposite to the electrically insulating layer 603 of the counterpart.

The printed wiring board 601 is formed in the above-described way.

In the manufacturing method, since the electromagnetic shielding layer 606 is transferred to the electrically insulating layers 603A and 603B after the electromagnetic shielding layer 606 is fixed on the transfer forming material 617, the electromagnetic shielding layer 606 is selectively formed in an optional region (leads 605, 604A, and 604B).

By providing the inner via inserting hole 608, the inner via hole 602 can be arranged apart from the electromagnetic shielding layer 606 or the insulating film 607, so that the conductive paste of the inner via hole 602 is not in contact with a constituent of the electromagnetic shielding layer 606 or the insulating film 607. Accordingly, the characteristics of the high-frequency signal which is transmitted through the inner via hole (conductive paste) 602 are suppressed to degrade.

The electromagnetic shielding layer 606 can be formed on both surfaces of the leads 605, 604A, and 604B in such a manner that the electromagnetic shielding layer 606 is formed again on the leads 605, 604A, and 604B after the transfer to the electrically insulating layers 603A and 603B. Consequently, compared to the structure in which the electromagnetic shielding layer 606 is formed on only one side of the leads 605, 604A, and 604B, the radiant noise can be further suppressed.

In the above-described manufacturing method, though the printed wiring board of the invention was made by the transfer method, the printed wiring board of the invention may be also made by adopting the subtractive method.

Though the embodiments of the invention were described in detail, the combination and the arrangement of the components for the embodiment can be variously changed without departing from the spirit and the scope of the invention as hereinafter claimed.

What is claimed is:

1. A printed wiring board comprising:
an insulating board which includes a plurality of electrically insulating layers which are laminated;
an electronic component which is built in the insulating board;
a signal transmitting lead which is provided at an interlayer between the electrically insulating layers;
an auxiliary lead which is provided on the insulating board while the auxiliary lead is not in electrical contact with the signal transmitting lead; and
an electromagnetic shielding layer which covers at least a part of the auxiliary lead.

2. A printed wiring board as claimed in claim 1, wherein the electromagnetic shielding layer is made of a magnetic material having magnetic loss.

3. A printed wiring board as claimed in claim 1, wherein the auxiliary lead is connected to ground potential.

4. A printed wiring board as claimed in claim 1, wherein an insulating film is provided between the auxiliary lead and the electromagnetic shielding layer.

5. A printed wiring board as claimed in claim 1, wherein the signal transmitting lead has lead regions which are opposite to each other, and the auxiliary lead is provided between the opposite lead regions.

6. A printed wiring board as claimed in claim 1, wherein the auxiliary lead is provided between the signal transmitting lead and the electronic component.

7. A printed wiring board as claimed in claim 1, wherein the auxiliary lead is provided opposite to a component surface in which strength of unnecessary radiation from the electronic component is higher in both component surfaces of the electronic component.

8. A printed wiring board as claimed in claim 1, wherein the auxiliary lead is provided opposite to a terminal forming surface of the electronic component.

9. A printed wiring board as claimed in claim 1, wherein the auxiliary lead is provided opposite to the component surface located on a reverse side of the terminal forming surface of the electronic component.

10. A printed wiring board as claimed in claim 1, wherein the auxiliary lead is provided opposite to the terminal forming surface of the electronic component and the component surface located on the reverse side of the terminal forming surface of the electronic component respectively.

11. A printed wiring board as claimed in claim 1, wherein the plurality of electronic components are provided, and the auxiliary lead is provided between the plurality of electronic components.

12. A printed wiring board as claimed in claim 1, wherein the auxiliary lead is provided on a periphery of the electronic component so as to surround the electronic component.

13. A printed wiring board as claimed in claim 1, wherein the auxiliary lead comprises a first auxiliary lead which covers one of the surfaces of the electronic component and a second auxiliary lead which is provided on the periphery of the electronic component so as to surround the electronic component, and
a conductor which electrically connects the first auxiliary lead to the second auxiliary lead is provided in the electrically insulating layer.

14. A printed wiring board as claimed in claim 13, wherein the plurality of conductors are provided so as to surround a side face of the electronic component, and the conductors are arranged so, that opposite directions of the conductors which are adjacent to each other are unparallel to a width direction of the side face of the electronic component and the opposite directions are intersected in sequence.

15. A printed wiring board as claimed in claim 1, wherein the electromagnetic shielding layer is provided on both surfaces of the auxiliary lead.

16. A printed wiring board as claimed in claim 1, wherein an electromagnetic shielding layer which covers at least a part of the signal transmitting lead is further provided.

17. A printed wiring board as claimed in claim 16, wherein both surfaces of the signal transmitting lead are covered with the electromagnetic shielding layer.

18. A printed wiring board as claimed in claim 16, wherein the insulating film is provided between the signal transmitting lead and the electromagnetic shielding layer which covers the signal transmitting lead.

19. A printed wiring board as claimed in claim 18, wherein the signal transmitting lead is provided on both surfaces of the electrically insulating layer respectively, the conductor which connects the signal transmitting leads on both surfaces are provided so that the conductor penetrates through the electrically insulating layer, and the insulating film and the electromagnetic shielding layer are arranged apart from the conductor.

20. A printed wiring board as claimed in claim 1, wherein the electrically insulating layer is made of a composite material which is formed by mixing an epoxy resin and an inorganic filler.

21. A printed wiring board as claimed in claim 1, wherein the auxiliary lead is connected to the ground potential and a length of the electromagnetic shielding layer is set to one fourth of a subject wavelength of suppression.

22. A printed wiring board as claimed in claim 1, wherein the length of the electromagnetic shielding layer is set to half the subject wavelength of the suppression.

23. A manufacturing method of a printed wiring board which includes an insulating board which includes a plurality of electrically insulating layers which are laminated, an electronic component which is built in the insulating board, a signal transmitting lead which is provided at an interlayer between the electrically insulating layers, an auxiliary lead which is provided on the insulating board in a state that the auxiliary lead is not in electrical contact with the signal transmitting lead, and an electromagnetic shielding layer which covers at least a part of the auxiliary lead, comprising the steps of:
preparing a transfer forming material and pattern-forming the auxiliary lead on the transfer forming material;
pattern-forming the electromagnetic shielding layer on the auxiliary lead layer on the transfer forming material; and
transferring the auxiliary lead from the transfer forming material to the electrically insulating layer by making the electromagnetic shielding layer about on the electrically insulating layer.

24. A manufacturing method of a printed wiring board as claimed in claim 23, further comprising the step of pattern-forming the electromagnetic shielding layer on the auxiliary lead layer which is transferred to the electrically insulating layer.
